(19) United States
(12) Patent Application Publication
(10) Pub. No.: US 2025/0336802 A1
(43) Pub. Date: Oct. 30, 2025

(54) Integrated Circuit with MIMCAP Having Reduced Contact Area

(71) Applicant: Texas Instruments Incorporated, Dallas, TX (US)

(72) Inventors: Manoj Jain, Plano, TX (US); Ye Shao, Dallas, TX (US); Haowen Bu, Wylie, TX (US); Bhaskar Srinivasan, Allen, TX (US); Honglin Guo, Dallas, TX (US)

(21) Appl. No.: 18/651,396

(22) Filed: Apr. 30, 2024

(51) Int. Cl. H01L 23/522; H01L 23/528; H01L 23/532

(52) U.S. Cl. CPC H01L 23/5223; H01L 23/5283; H10D 1/692; H01L 23/53228

(57) ABSTRACT

Integrated circuit devices, and related methods of manufacturing, that include a metal-insulator-metal capacitor (MIMCAP) in a dielectric layer over a semiconductor substrate. The MIMCAP has a top plate and a bottom plate having a lateral perimeter defining a bottom plate lateral area. A first metal interconnect layer over the MIMCAP is connected to the top plate. A second metal interconnect layer below the MIMCAP touches the bottom plate. A contact area between the second metal interconnect layer and the bottom plate is less than the bottom plate lateral area.

### BACKGROUND OF THE DISCLOSURE

Integrated circuit (IC) devices often include transistors and capacitors, among other semiconductor-based components. For example, a metal-insulator-metal capacitor (MIMCAP) is generally considered to be an important passive component in IC devices, including radio frequency (RF) and analog ICs. MIMCAPs can permit high capacitance density that utilizes a relatively small chip area which increases circuit density, and further reduces the IC fabrication cost. However, such IC fabrication cost is conversely related to product yield, such as may be reduced due to low breakdown voltage of such capacitors, among other factors.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an IC that includes a MIMCAP in a dielectric layer over a semiconductor substrate, a first metal interconnect layer over the MIMCAP, and a second metal interconnect layer below the MIMCAP. The MIMCAP has a top plate and a bottom plate having a lateral perimeter defining a bottom plate lateral area. The first metal interconnect layer is connected to the top plate. The second metal interconnect layer touches the bottom plate. A contact area between the second metal interconnect layer and the bottom plate is less than the bottom plate lateral area.

The present disclosure also introduces a method of manufacturing an IC device, in which a plurality of layers is formed over a semiconductor substrate, including a lower metal layer and at least one dielectric layer over the lower metal layer. A plurality of openings are formed in the at least one dielectric layer, thereby exposing portions of an upper surface of the lower metal layer. Each of the openings are lined with an outer conductive layer contacting the lower metal layer, an inner conductive layer, and a nonconductive layer interposing the inner and outer conductive layers. The method also includes forming a plurality of conductive plugs each filling a corresponding one of the lined openings, forming a plurality of vias each contacting a corresponding one of the conductive plugs, and forming an upper metal layer contacting each of the vias. A contact area between each outer conductive layer and the lower metal layer is less than a bottom surface area of that outer conductive layer.

The present disclosure also introduces an IC device that includes a plurality of layers formed over a semiconductor substrate, including a lower metal layer, an upper metal layer, and at least one dielectric layer interposing the lower and upper metal layers. The IC device also includes a plurality of metal plates each having a bottom surface. A contact area between each metal plate and the lower metal layer extends from a first side of a perimeter of that metal plate to an opposite side of the perimeter, and is less than a bottom surface area of that metal plate.

These and additional aspects of the present disclosure are set forth in the description that follows, and/or may be learned by a person skilled in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In some cases, the dimensions of the various features may be arbitrarily increased or reduced for clarity of discussion.

FIG. 1 is a plan view of a portion of an example implementation of an IC comprising MIMCAPs.

FIG. 2 is a sectional view of the IC portion shown in FIG. 1.

FIG. 3 is a sectioned perspective view of the IC portion shown in FIGS. 1 and 2.

FIG. 4 is a plot depicting cumulative probability of breakdown voltage of the MIMCAPs depicted in FIGS. 1-3.

FIG. 5 is a plan view of a portion of an example implementation of an IC comprising MIMCAPs according to one or more aspects introduced in the present disclosure.

FIG. 6 is a sectional view of the IC portion shown in FIG. 5.

FIG. 7 is a sectioned perspective view of the IC portion shown in FIGS. 5 and 6.

FIG. 8 is a plot depicting cumulative probability of breakdown voltage of the MIMCAPs depicted in FIGS. 5-7.

FIGS. 9-13 are sectional views of a portion of an example implementation of an IC in various stages of manufacture according to one or more aspects introduced in the present disclosure.

FIGS. 14-17 are plan views of portions of additional example implementations of ICs comprising MIMCAPs according to one or more aspects introduced in the present disclosure.

### DETAILED DESCRIPTION

It is to be understood that the following disclosure provides many different examples for different features of various implementations. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various examples and/or configurations discussed. Moreover, the formation of a first feature over or on a second feature in the description that follows may include examples in which the first and second features are formed in direct contact, and may also include examples in which additional features may be formed interposing the first and second features, such that the first and second features may not be in direct contact.

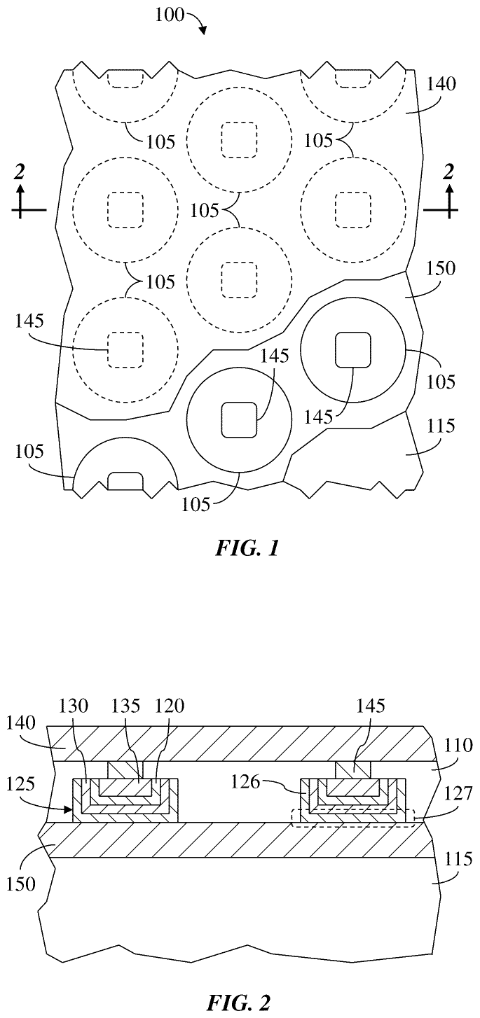

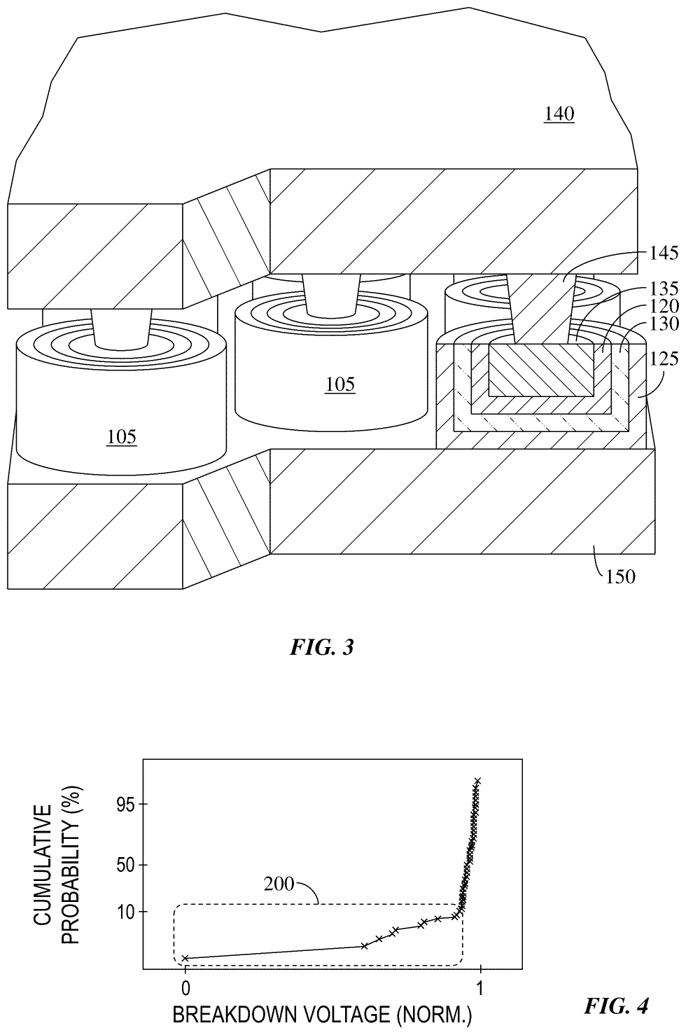

FIG. 1 is a plan view of a portion of an IC 100 comprising a plurality of MIMCAPs 105 in a dielectric layer 110 over a semiconductor substrate 115 and interconnected in a baseline implementation. FIG. 2 is a side sectional view of the portion of the IC 100 shown in FIG. 1. FIG. 3 is a perspective view of the portion of the IC 100 shown in FIG. 1 excluding the dielectric layer 110. The following description refers to FIGS. 1-3, collectively.

Each MIMCAP 105 may have one or more aspects as described in U.S. Pat. No. 11,075,157, which is hereby incorporated herein by reference. For example, each MIMCAP 105 has metal top and bottom plates 120, 125. The bottom plate 125 is generally cup-shaped, having a cylindrical wall 126 extending upward from a lower disc-shaped portion 127. An insulator 130 lines the inside surfaces of bottom plate 125, thus electrically insulating the bottom plate 125 from the top plate 120. As depicted in FIGS. 2 and 3, the top plate 120 may also be generally cup-shaped, lining side and bottom surfaces of a conductive plug 135, although in other implementations the top plate 120 and the plug 135 may be a single unified member.

The IC also comprises an upper metal interconnect layer 140 over the MIMCAPs 105 and connected to each MIMCAP 105 by a corresponding via 145. A lower metal interconnect layer 150 contacts the bottom plates 125 of each MIMCAP 105. The lower metal interconnect 150 layer interconnects the MIMCAPs 105 to form a first terminal of an array capacitor and the upper metal interconnect layer 140 interconnects the MIMCAPs 105 to form a second terminal of the array capacitor. The lower interconnect layer 150 is a contiguous plate, such that a contact area between the lower interconnect layer 150 and each bottom plate 125 is equal to the surface area of the bottom of the bottom plate 125.

FIG. 4 is a normal probability plot showing cumulative probability (%) of breakdown voltage (normalized) of MIMCAPs similar to those depicted in FIGS. 1-3. The plot demonstrates that in the baseline implementation the breakdown voltage of a subset 200 (roughly 10%) of the MIMCAPs tested deviated significant from normality. It is believed that that expansion of the underlying interconnect layer 150 causes the breakdown voltage failures depicted in the plot by weakening the structure of the MIMCAPs 105. It is further believed that the fraction of the perimeter of the bottom plate 125 that overlaps the lower interconnect layer 150 may also be causally related to the incidence of MIMCAP 105 breakdown. As a result of their investigation, the inventors have determined that decreasing the contact area between the underlying interconnect layer 150 and the bottom of the MIMCAPs 105 provides a surprising and unexpected improvement of the breakdown voltage variability of the MIMCAPs 105.

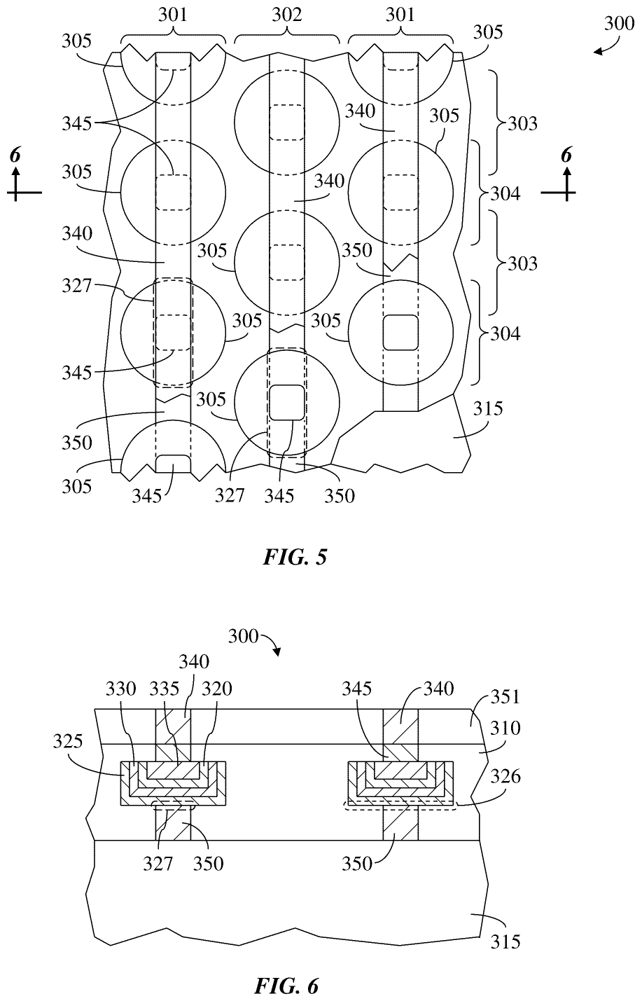

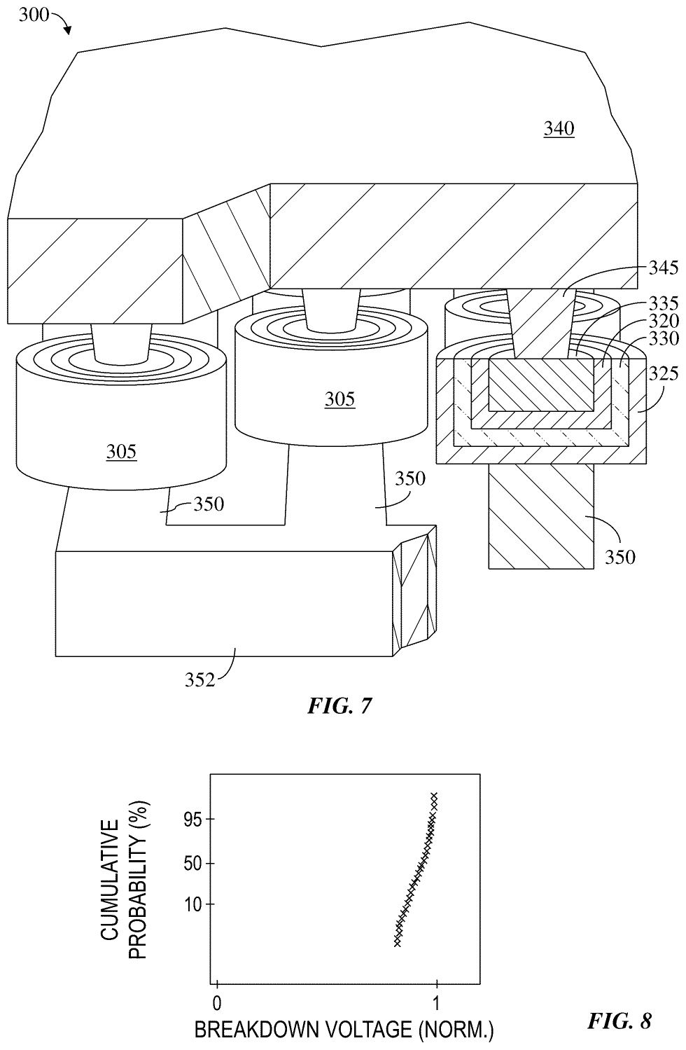

For example, FIG. 5 is a plan view of a portion of an example implementation of an IC 300 according to one or more aspects introduced in the present disclosure. The IC 300 comprises a plurality of MIMCAPs 305 in a dielectric layer 310 over a semiconductor substrate 315. FIG. 6 is a side sectional view of the portion of the IC 300 shown in FIG. 5. FIG. 7 is a perspective view of the portion of the IC 300 shown in FIG. 5 excluding the dielectric layer 310. The following description refers to FIGS. 5-7, collectively.

Each MIMCAP 305 may be, and in the illustrated example is shown as substantially similar to the MIMCAPs 105 described above, including metal top and bottom plates 320, 325 similar to the respective top and bottom plates 120, 125, an insulator 330 similar to the insulator 130, and a conductive plug 335 similar to the conductive plug 135. However, instead of the contiguous plate formed by the lower metal interconnect layer 150, the IC 300 includes a plurality of rectilinear or otherwise elongated lower metal interconnects 350 interconnecting subsets of the MIMCAPs 305. That is, the lower metal interconnects 350 are metal traces that touch one or more bottom plates 325 and have a linewidth less than the diameter of the bottom plates 325. In some examples, and as illustrated, the linewidth is about equal to a width of the via 345 contacting the top of the MIMCAP 305.

Thus, similar to the MIMCAPs 105 described above, the bottom plates 325 of the MIMCAPs 305 have a lateral perimeter defining a bottom plate lateral area 326. However, the contact area 327 between the lower metal interconnects 350 and the corresponding bottom plates 325 is less than the bottom plate lateral area 326. For example, in the implementation depicted in FIGS. 5-7, the contact area 327 is approximately 40% of the bottom plate lateral area 326. However, in other implementations within the scope of the present disclosure, the contact area 327 may be 20% to 80% of the bottom plate lateral area 326, depending on, e.g., the diameter of the bottom plate 325 and the width of the via 345. In other implementations within the scope of the present disclosure, the contact area 327 may be 30% to 50% of the bottom plate lateral area 326, e.g., to provide an effective reduction of overlap of a perimeter 327 of the bottom plate 325 and the lower metal interconnects 350.

As depicted in FIG. 5, the MIMCAPs 305 are arranged in linear sets, arrays, or “columns” 301, 302, as well as rows 303, 304. Such arrangement may be also referred to as a hexagonal array. Each rectilinear lower metal interconnect 350 interconnects the MIMCAPs 305 of a corresponding one of the columns 301, 302. Each column 301, 302 is staggered relative to its neighboring columns 301, 302, such that each row 303, 304 does not comprise a MIMCAP 305 in neighboring columns 301, 302. Such arrangement permits a high capacitance density in a relatively small chip area, thereby increasing circuit density.

As depicted in FIG. 6, the interlayer dielectric 310 laterally interposes the lower metal interconnects 350, and an interlayer dielectric 351 laterally interposes upper metal interconnects 340. As depicted in FIG. 7, the lower metal interconnects 350 may be interconnected by additional portions 352 of the same metal layer.

As with the IC 100 described above, the IC 300 includes an upper metal interconnect layer connected to the MIMCAPs 305 by vias 345. In FIGS. 5 and 6, the upper metal interconnect layer is depicted as a plurality of rectilinear or otherwise elongated upper metal interconnects 340, each having the same dimensions as the lower metal interconnects 350. However, in other implementations also within the scope of the present disclosure, the upper metal interconnects 340 may be shaped differently from the lower metal interconnects 350. For example, as depicted in FIG. 7, the upper metal interconnects 340 depicted in FIGS. 5 and 6 may be replaced with a contiguous plate similar to the upper metal interconnect layer 140 depicted in FIGS. 1-3. In either case, the lower metal interconnects 350 interconnect the MIMCAPs 305 to form a first terminal of an array capacitor and the upper metal interconnects 340 interconnect the MIMCAPs 305 to form a second terminal of the array capacitor.

FIG. 8 is a normal probability plot showing cumulative probability (%) of breakdown voltage (normalized) of MIMCAPs similar to those depicted in FIGS. 5-7. The graph demonstrates that, as a result of reducing the contact area between the lower metal interconnects 350 and the MIMCAPs 305, the low breakdown voltage outliers described above may be reduced or eliminated in implementations consistent with the present disclosure.

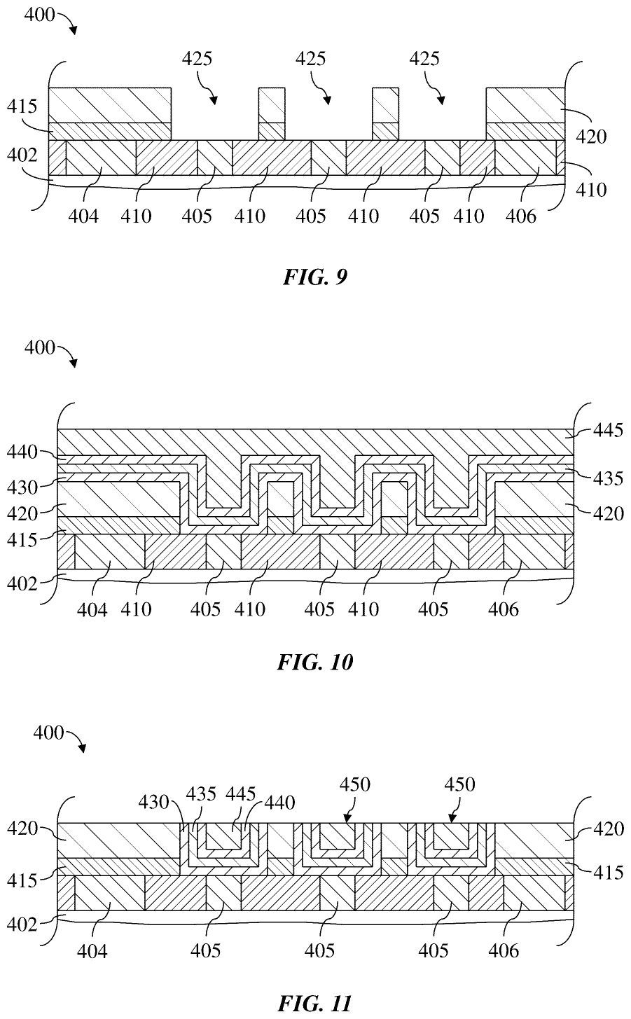

FIG. 9 is a sectional view of a portion of an example implementation of an IC 400 in an intermediate stage of manufacture according to one or more aspects of the present disclosure. Upon completion, the IC 400 will include a plurality of MIMCAPs having one or more aspects in common with the MIMCAPs 305 described above.

The IC 400 includes metal interconnects 404, 405, 406 formed in openings of a dielectric layer 410 over a substrate 402. The metal interconnects 404-406 may be aluminum, copper, or other conductive materials deposited by chemical vapor deposition (CVD) and/or other deposition processes. The metal interconnects 405 will form lower interconnects of the MIMCAPs, such as the interconnects 350 shown in FIGS. 5-7.

A silicon nitride (SiN) or other insulating layer 415 is formed on the interconnects 404-406 and the dielectric layer 410, such as by CVD and/or other processes. Another dielectric layer 420 is formed on the insulating layer 415, such as silicon dioxide (SiO2) grown by a tetraethyl orthosilicate (TEOS) process or other CVD method. The dielectric layer 420 and the insulating layer 415 are patterned, such as by photolithography and plasma etch, to form openings (e.g., trenches) 425 where the MIMCAPs will be formed.

FIG. 10 is a sectional view of the IC 400 in a subsequent stage of manufacturing. A metal layer 430 is formed on the exposed surfaces of the dielectric layer 420, the insulating layer 415, the metal interconnects 405, and the dielectric layer 410, including the sidewalls of the openings 425. The metal layer 430 may be tantalum/tantalum nitride (Ta/TaN) and/or other metallic materials deposited by CVD and/or other deposition processes. The metal layer 430 will form the bottom plates of the MIMCAPs, such as the bottom plates 325 shown in FIGS. 5-7.

An insulator layer 435 is formed on the exposed surfaces of the metal layer 430. The insulator layer 435 may be oxide-nitride-oxide (ONO) dielectric and/or other insulating materials deposited by CVD and/or other deposition processes. The insulator layer 435 will serve as a capacitor dielectric of the insulators of the MIMCAPs, such as the insulators 330 shown in FIGS. 5-7.

Another metal layer 440 is formed on the exposed surfaces of the insulator layer 435, The metal layer 440 may be Ta/TaN and titanium/titanium nitride or other metallic materials deposited by CVD and/or other deposition processes. Optionally, the metal layer 430 and the metal layer 440 may have about a same thickness. The metal layer 440 will form the top plates of the MIMCAPs, such as the top plates 320 shown in FIGS. 5-7.

Another metal layer 445 is formed on the exposed surfaces of the metal layer 440. The metal layer 445 may be tungsten or other metallic materials deposited by CVD and/or other deposition processes. The metal layer 445 will form the conductive plugs of the MIMCAPs, such as the conductive plugs 335 shown in FIGS. 5-7.

In a subsequent stage of manufacturing, as depicted in FIG. 11, chemical-mechanical planarizing and/or other material removal processes have removed portions of the metal layer 445, metal layer 440, insulator layer 435, and metal layer 430 above the dielectric layer 420. Thus, MIMCAPs 450 having conductive plugs 446 have been formed in the previously formed openings 425 in the dielectric layer 420 and the insulating layer 415.

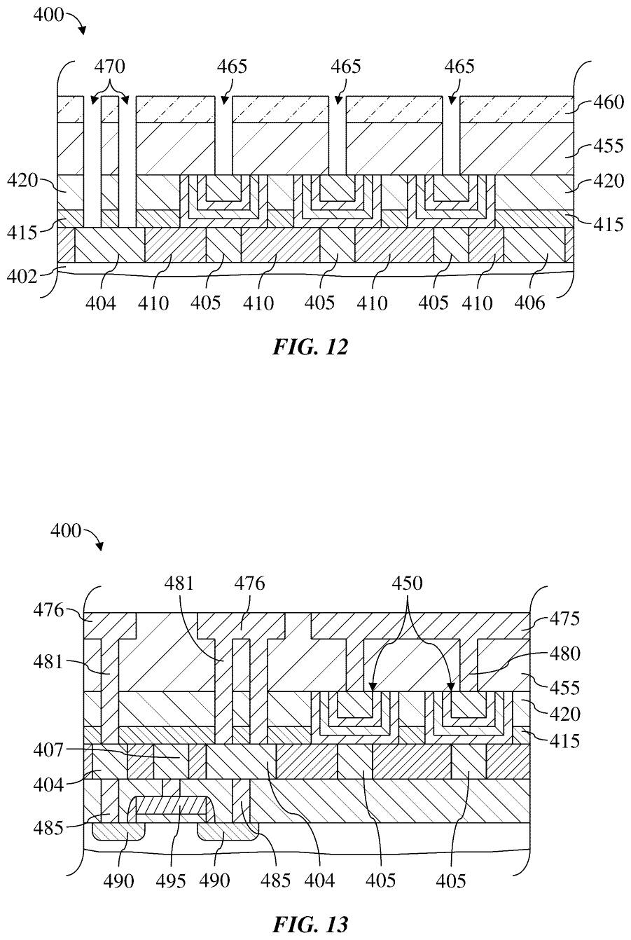

FIG. 12 is a sectional view of the IC 400 in a subsequent stage of manufacturing in which a dielectric layer 455 has been formed over the exposed surfaces of the MIMCAPs 450 and the dielectric layer 420. A patterned photoresist layer 460 is utilized to form openings 465 in the dielectric layer 455 to expose a top surface of each MIMCAP 450, as well as openings 470 extending through the dielectric layer 455, the dielectric layer 420, and the insulating layer 415 to expose a top surface of the metal interconnect 404.

FIG. 13 is a sectional view of a portion of the IC 400 in a subsequent stage of manufacture in which a metal has been deposited in the openings 465, 470, resulting in the formation of metal interconnects 475 connected to vias 480, and metal interconnect 476 connected to vias 481. The vias 480 extend through the dielectric layer 455 and contact the conductive plugs 446 of the MIMCAPs 450. The vias 481 extend through the dielectric layer 455, the dielectric layer 420, and the insulating layer 415 and contact the metal interconnects 404. The metal interconnects 404 are connected by corresponding contacts 485 to source/drain regions 490 of a transistor formed in the substrate 402. A gate 495 of the transistor is similarly connected to another metal interconnect 407.

As described above with respect to FIGS. 5-7, the contact area between the lower metal interconnects 405 and the bottom plate of each MIMCAPs 450 is smaller than the bottom plate surface area of the MIMCAPs 450. Also, although the interconnections to the MIMCAPs 450 are depicted in FIG. 13 as being in the first metal layer of the IC 400 (the lower metal interconnects 405) and the second metal layer of the IC 400 (the upper metal interconnect 475), other metal layers (not shown) of the IC 400 may instead or alternatively be utilized for interconnecting the MIMCAPs 450 to each other and/or the transistor and/or other devices integral to the IC 400.

Furthermore, although the MIMCAPs 450 are generally coupled to nodes in the circuitry of the IC 400, it is also possible for the plates of the MIMCAPs 450 to be provided as separate pins of an IC. Example circuit functions include analog (e.g., amplifier or power converter), radio frequency (RF), digital, or non-volatile memory functions. The capability of the IC 400 may vary, ranging from a simple device to a complex device.

FIG. 14 is a plan view of a portion of an IC 500 according to one or more aspects introduced in the present disclosure. The IC 500 is another example implementation of an IC having an array capacitor including the MIMCAPs 305. In the IC 300 shown in FIGS. 5-7, each lower metal interconnect 350 has a rectilinear shape that extends along a vertical axis so as to interconnect each MIMCAP 305 of a corresponding one of the columns 301. However, in the IC 500, each lower metal interconnect 550 interconnects MIMCAPs 305 in two neighboring columns 301, 302, thus extending along two non-colinear axes. The lower metal interconnects 550 may otherwise be substantially similar to the lower metal interconnects 350 of the IC 300 shown in FIGS. 5-7. For example, the contact area between each MIMCAP 305 and its underlying interconnect 550 is less than the bottom plate lateral area of that MIMCAP 305 and about a same width as the vias 345.

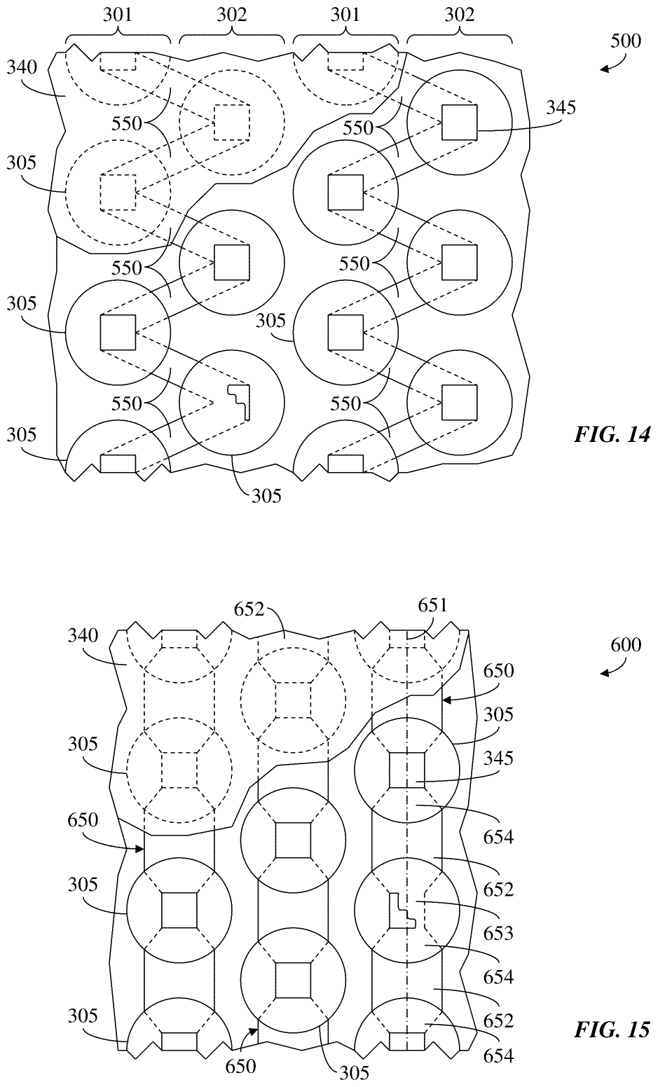

FIG. 15 is a plan view of a portion of an IC 600 according to one or more aspects introduced in the present disclosure. The IC 600 is another example implementation of an IC having an array capacitor including the MIMCAPs 305. In the IC 300 shown in FIGS. 5-7, each lower metal interconnect 350 has a rectilinear shape of constant width. However, each lower metal interconnect 650 of the IC 600 is a trace touching the bottom of each corresponding MIMCAP 305 and having a path along a single vertical axis 651 and a linewidth (perpendicular to the axis 651) that decreases from greater than the width of the vias 345 to about the width of the vias 345 where the lower metal interconnects 650 touch the bottom plates 325. That is, each lower metal interconnect 650 may have a varying width, including wide portions 652 between the neighboring interconnected MIMCAPs 305, narrow portions 653 below the via 345, and transition portions 654 tapering between each neighboring pair of wide and narrow portions 652, 653. The narrow portions 653 depicted in FIG. 15 have the same line width as the vias 345, but other widths are also possible. The wide portions 652 have a linewidth that is greater than the line width of the narrow portions 653 but less than the lateral diameter of the MIMCAP 305. The IC 600 is an example implementation demonstrating that the portions of the lower interconnects directly beneath the MIMCAPs are not constrained to be the minimum width (e.g., the width of the vias 345). The lower metal interconnects 650 may otherwise be substantially similar to the lower metal interconnects 350 of the IC 300 shown in FIGS. 5-7.

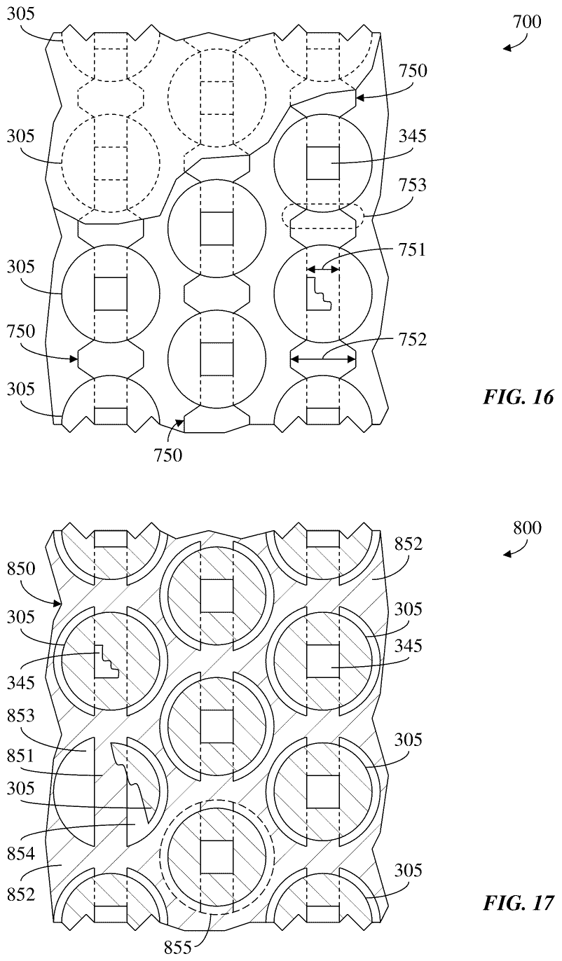

FIG. 16 is a plan view of a portion of an IC 700 according to one or more aspects introduced in the present disclosure. The IC 700 is another example implementation of an IC having an array capacitor including the MIMCAPs 305. In the IC 700, lower metal interconnects 750 have a first width 751 inside the lateral perimeters of the MIMCAPs 305 a second greater width 752 outside the lateral perimeters of the MIMCAPs 305, as well as transition portions 753 tapering between the first and second widths 751, 752. The first width 751 may be as small the width of the vias 345, and the second width 752 is greater than the first width 751, and may be any width between the MIMCAPs 305. The lower metal interconnects 750 may otherwise be substantially similar to the lower metal interconnects 350 of the IC 300 shown in FIGS. 5-7.

FIG. 17 is a plan view of a portion of an IC 800 according to one or more aspects introduced in the present disclosure. The IC 800 is another example implementation of an IC having an array capacitor including the MIMCAPs 305. In the IC 800, the lower metal interconnects include trace portions 851 in a lower metal layer 850, each trace portion 851 being separated from a solid planar portion 852 by corresponding first and second cutouts 853, 854. The first and second cutouts 853, 854 may each describe a cutout perimeter 855, the lateral perimeter of the MIMCAP 305 being inside the cutout perimeter 855. The lower metal interconnects of the IC 800 may otherwise be substantially similar to the lower metal interconnects 350 of the IC 300 shown in FIGS. 5-7.

In view of the entirety of the present disclosure, including the figures and the claims, a person skilled in the art will readily recognize that the present disclosure introduces an IC comprising: a MIMCAP in a dielectric layer over a semiconductor substrate, the MIMCAP having a top plate and a bottom plate having a lateral perimeter defining a bottom plate lateral area; a first metal interconnect layer over the MIMCAP connected to the top plate; and a second metal interconnect layer below the MIMCAP touching the bottom plate, a contact area between the second metal interconnect layer and the bottom plate being less than the bottom plate lateral area.

The second metal interconnect layer may include a metal trace touching the bottom plate and having a path and a linewidth less than a lateral diameter of the bottom plate at an intersection of the path and the lateral perimeter.

The MIMCAP may include an ONO dielectric layer between the top plate and the bottom plate.

The first interconnect layer may be connected to the MIMCAP by a via and the second metal interconnect layer may include a metal trace that touches the bottom plate and that has a linewidth about equal to a width of the via.

The MIMCAP may be one of a plurality of MIMCAPs arranged in linear arrays, the MIMCAPs of each linear array connected to one of a corresponding plurality of traces in the second interconnect layer. The plurality of traces may have a first width inside the lateral perimeters of the bottom plates and a second greater width outside the lateral perimeters of the bottom plates.

The second interconnect level may include a solid planar portion having first and second cutouts separated by a trace portion that touches the bottom plate. The first and second cutouts may describe a cutout perimeter, the lateral perimeter of the bottom plate being inside the cutout perimeter.

The first and second metal interconnect layers may be copper interconnect layers.

The IC may further comprise a transistor extending into the semiconductor substrate and interconnected with the MIMCAP.

The present disclosure also introduces a method of manufacturing an IC device, the method comprising: forming a plurality of layers over a semiconductor substrate, including a lower metal layer and at least one dielectric layer over the lower metal layer; forming a plurality of openings in the at least one dielectric layer, thereby exposing portions of an upper surface of the lower metal layer; lining each of the openings with an outer conductive layer contacting the lower metal layer, an inner conductive layer, and a nonconductive layer interposing the inner and outer conductive layers; forming a plurality of conductive plugs each filling a corresponding one of the lined openings; forming a plurality of vias each contacting a corresponding one of the conductive plugs; and forming an upper metal layer contacting each of the vias; wherein a contact area between each outer conductive layer and the lower metal layer is less than a bottom surface area of that outer conductive layer.

The vias and the upper metal layer may collectively be formed during a single deposition.

The outer conductive layer, the inner conductive layer, and the interposing nonconductive layer within each opening may collectively be one of a plurality of capacitors each formed in a corresponding one of the openings, and the method may further comprise forming a transistor at least partially in the semiconductor substrate and interconnected with at least one of the capacitors.

Each nonconductive layer may be an ONO dielectric layer.

Forming the lower metal layer may comprise depositing a solid planar portion having pairs of first and second cutouts each separated by a corresponding trace portion, each trace portion touching a corresponding one of the outer conductive layers.

The present disclosure also introduces an IC device comprising: a plurality of layers formed over a semiconductor substrate and including a lower metal layer, an upper metal layer, and at least one dielectric layer interposing the lower and upper metal layers; and a plurality of metal plates each having a bottom surface. A contact area between each metal plate and the lower metal layer: extends from a first side of a perimeter of that metal plate to an opposite side of the perimeter; and is less than a bottom surface area of that metal plate.

Each metal plate may be a bottom plate of a corresponding one of a plurality of trench capacitors. The lower metal layer and the metal plates may form a first terminal of an array capacitor. The lower metal layer may comprise a plurality of rectilinear members, the plurality of trench capacitors may include a plurality of capacitor sets, and the trench capacitors of each capacitor set may be interconnected by a corresponding one of the rectilinear members. The lower metal layer may comprise a plurality of nonrectilinear members, the plurality of trench capacitors may include a plurality of capacitor sets, and the trench capacitors of each capacitor set may be interconnected by a corresponding one of the nonrectilinear members. The lower metal layer may comprise a plurality of members, the plurality of trench capacitors may include a plurality of capacitor sets, the trench capacitors of each capacitor set may be interconnected by a corresponding one of the members, and each member may have a width alternating from: a first width at junctions with the trench capacitors of the corresponding capacitor set; and a second width at locations between the trench capacitors of the corresponding capacitor set, wherein the second width is greater than the first width. The integrated circuit device may further comprise a transistor formed at least partially in the semiconductor substrate and interconnected with at least one of the trench capacitors.

Each nonconductive layer may be an ONO dielectric layer.

The contact area between each metal plate and the lower metal layer may be at least 20% less than the bottom surface area of that metal plate.

The lower and upper metal layers may be aluminum.

The foregoing outlines features of several examples so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the examples introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to comply with 37 C.F.R. § 1.72(b) to permit the reader to quickly ascertain the nature of the technical disclosure. It is submitted with the understanding that it will not be used to interpret or limit the scope or meaning of the claims.

What is claimed is:

1. An integrated circuit (IC), comprising:
a metal-insulator-metal capacitor (MIMCAP) in a dielectric layer over a semiconductor substrate, the MIMCAP having a top plate and a bottom plate having a lateral perimeter defining a bottom plate lateral area;
a first metal interconnect layer over the MIMCAP connected to the top plate; and
a second metal interconnect layer below the MIMCAP touching the bottom plate, a contact area between the second metal interconnect layer and the bottom plate being less than the bottom plate lateral area.

2. The IC of claim 1 wherein the second metal interconnect layer includes a metal trace touching the bottom plate and having a path and a linewidth less than a lateral diameter of the bottom plate at an intersection of the path and the lateral perimeter.

3. The IC of claim 1 wherein the MIMCAP includes an oxide-nitride-oxide (ONO) dielectric layer between the top plate and the bottom plate.

4. The IC of claim 1 wherein the first interconnect layer is connected to the MIMCAP by a via and the second metal interconnect layer includes a metal trace that touches the bottom plate and has a linewidth about equal to a width of the via.

5. The IC of claim 1 wherein the MIMCAP is one of a plurality of MIMCAPs arranged in linear arrays, the MIMCAPs of each linear array connected to one of a corresponding plurality of traces in the second interconnect layer.

6. The IC of claim 5 wherein the plurality of traces have a first width inside the lateral perimeters of the bottom plates and a second greater width outside the lateral perimeters of the bottom plates.

7. The IC of claim 1 wherein the second interconnect level includes a solid planar portion having first and second cutouts separated by a trace portion that touches the bottom plate.

8. The IC of claim 7 wherein the first and second cutouts describe a cutout perimeter, the lateral perimeter of the bottom plate being inside the cutout perimeter.

9. The IC of claim 1 wherein the first and second metal interconnect layers are copper interconnect layers.

10. The IC of claim 1 further comprising a transistor extending into the semiconductor substrate and interconnected with the MIMCAP.

11. A method of manufacturing an integrated circuit device, the method comprising:
forming a plurality of layers over a semiconductor substrate, including a lower metal layer and at least one dielectric layer over the lower metal layer;
forming a plurality of openings in the at least one dielectric layer, thereby exposing portions of an upper surface of the lower metal layer;
lining each of the openings with:
an outer conductive layer contacting the lower metal layer;
an inner conductive layer; and
a nonconductive layer interposing the inner and outer conductive layers;
forming a plurality of conductive plugs each filling a corresponding one of the lined openings;
forming a plurality of vias each contacting a corresponding one of the conductive plugs; and
forming an upper metal layer contacting each of the vias;
wherein a contact area between each outer conductive layer and the lower metal layer is less than a bottom surface area of that outer conductive layer.

12. The method of claim 11 wherein the vias and the upper metal layer are collectively formed during a single deposition.

13. The method of claim 11 wherein:
the outer conductive layer, the inner conductive layer, and the interposing nonconductive layer within each opening are collectively one of a plurality of capacitors each formed in a corresponding one of the openings; and
the method further comprises forming a transistor at least partially in the semiconductor substrate and interconnected with at least one of the capacitors.

14. The method of claim 11 wherein each nonconductive layer is an oxide-nitride-oxide (ONO) dielectric layer.

15. The method of claim 11 wherein forming the lower metal layer comprises depositing a solid planar portion having pairs of first and second cutouts each separated by a corresponding trace portion, each trace portion touching a corresponding one of the outer conductive layers.

16. An integrated circuit device, comprising:
a plurality of layers formed over a semiconductor substrate and including a lower metal layer, an upper metal layer, and at least one dielectric layer interposing the lower and upper metal layers; and
a plurality of metal plates each having a bottom surface, wherein a contact area between each metal plate and the lower metal layer:
extends from a first side of a perimeter of that metal plate to an opposite side of the perimeter; and
is less than a bottom surface area of that metal plate.

17. The integrated circuit device of claim 16 wherein each metal plate is a bottom plate of a corresponding one of a plurality of trench capacitors.

18. The integrated circuit device of claim 17 wherein the lower metal layer and the metal plates form a first terminal of an array capacitor.

19. The integrated circuit device of claim 17 further comprising a transistor formed at least partially in the semiconductor substrate and interconnected with at least one of the trench capacitors.

20. The integrated circuit device of claim 16 wherein the contact area between each metal plate and the lower metal layer is at least 20% less than the bottom surface area of that metal plate.
